(19) United States
(12) Patent Application Publication
(10) Pub. No.: US 2024/0153981 A1
(43) Pub. Date: May 9, 2024

(54) SOLID-STATE IMAGING DEVICE

(71) Applicant: SONY SEMICONDUCTOR SOLUTIONS CORPORATION, Kanagawa (JP)

(72) Inventors: Hidetoshi OISHI, Kanagawa (JP); Hiroaki AMMO, Kanagawa (JP); Shinichi MIYAKE, Kanagawa (JP)

(73) Assignee: SONY SEMICONDUCTOR SOLUTIONS CORPORATION, Kanagawa (JP)

(21) Appl. No.: 18/549,450

(22) PCT Filed: Feb. 8, 2022
(86) PCT No.: PCT/JP2022/004900

§ 371 Date: Sep. 7, 2023

(30) Foreign Application Priority Data
Mar. 15, 2021 (JP) 2021-041892

(51) Int. Cl. H01L 27/146; H01L 23/00; H01L 29/78; H01L 29/94

(52) U.S. Cl. CPC H01L 27/14634; H01L 24/08; H01L 27/14614; H01L 27/14636; H01L 29/78391; H01L 29/94; H01L 2224/08145

(57) ABSTRACT

A solid-state imaging device is provided that enables miniaturization of a pixel and improvement in electrical properties of a transistor of a pixel circuit. The solid-state imaging device includes a first semiconductor layer and a second semiconductor layer. In the first semiconductor layer, a pixel including a photoelectric converter is arranged in a matrix along a plane direction. The number of the pixel is two or more. The second semiconductor layer is stacked on the first semiconductor layer on an opposite side to a light-incoming side of the pixel. In the second semiconductor layer, a first transistor electrically coupled to the pixel is provided. A gate lengthwise direction of the first transistor is inclined with respect to an arrangement direction of the pixel.

### TECHNICAL FIELD

The present disclosure relates to a solid-state imaging device.

### BACKGROUND ART

PTL 1 discloses an imaging device. In the imaging device, a second substrate is stacked on a first substrate. Pixels (sensor pixels) that perform photoelectric conversion are disposed in the first substrate. A pixel circuit (a reading circuit) that outputs pixel signals based on charge outputted from the pixels is disposed in the second substrate.

In the imaging device, the pixels and the pixel circuit are separately disposed in the different substrates. This makes it possible to secure a sufficient space to dispose the pixel circuit irrespective of advancement in miniaturization of the pixels.

### CITATION LIST

### Patent Literature

PTL 1: International Publication No. WO2019/131965A1

### SUMMARY OF THE INVENTION

The above-described imaging device has experienced a trend toward further miniaturization of pixels. The miniaturization of the pixels leads to a reduction in area to dispose a transistor of a pixel circuit disposed in accordance with the pixels. Accordingly, there is room for improvement in order to prevent occurrence of a short channel effect and effectively suppress an influence of noise to improve properties of the transistor.

The present disclosure provides a solid-state imaging device enabling miniaturization of pixels and improvement in electrical properties of a transistor of a pixel circuit.

A solid-state imaging device according to an embodiment of the present disclosure includes a first semiconductor layer and a second semiconductor layer. In the first semiconductor layer, a pixel is arranged in a matrix along a plane direction. The pixel includes a photoelectric converter. The number of pixel is two or more. The second semiconductor layer is stacked on the first semiconductor layer on an opposite side to a light-incoming side of the pixel and includes a first transistor. The first transistor is electrically coupled to the pixel and has a gate lengthwise direction inclined with respect to an arrangement direction of the pixel.

### BRIEF DESCRIPTION OF DRAWINGS

FIG. 1 is a schematic plan view of a pixel circuit of a solid-state imaging device according to a first embodiment of the present disclosure.

FIG. 2 is a schematic cross-sectional view of the solid-state imaging device including the pixel circuit illustrated in FIG. 1.

FIG. 3 is a circuit diagram including pixels and the pixel circuit of the solid-state imaging device illustrated in FIG. 1 and FIG. 2.

FIG. 4 is a circuit diagram, which corresponds to FIG. 3, of a solid-state imaging device according to a second embodiment of the present disclosure.

FIG. 5 is a schematic plan view, which corresponds to FIG. 1, of a pixel circuit of the solid-state imaging device illustrated in FIG. 4.

FIG. 6 is a schematic cross-sectional view, which corresponds to FIG. 2, of a main part, illustrating pixels and a pixel circuit of a solid-state imaging device according to a third embodiment of the present disclosure.

FIG. 7 is a schematic plan view, which corresponds to FIG. 1, of a pixel circuit of a solid-state imaging device according to a fourth embodiment of the present disclosure.

FIG. 8 is a schematic plan view, which corresponds to FIG. 1, of a pixel circuit of a solid-state imaging device according to a fifth embodiment of the present disclosure.

FIG. 9 is a schematic cross-sectional view, which corresponds to FIG. 2, of a main part, illustrating pixels and a pixel circuit of a solid-state imaging device according to a sixth embodiment of the present disclosure.

FIG. 10 is a schematic cross-sectional view of a capacitor to be mounted on a solid-state imaging device according to a seventh embodiment of the present disclosure.

FIG. 11 is a schematic cross-sectional view of a resistor to be mounted on a solid-state imaging device according to an eighth embodiment of the present disclosure.

FIG. 12 is a schematic cross-sectional view of a memory element to be mounted on a solid-state imaging device according to a ninth embodiment of the present disclosure.

FIG. 13 is a block diagram depicting an example of schematic configuration of a vehicle control system.

FIG. 14 is a diagram of assistance in explaining an example of installation positions of an outside-vehicle information detecting section and an imaging section.

FIG. 15 is a view depicting an example of a schematic configuration of an endoscopic surgery system.

FIG. 16 is a block diagram depicting an example of a functional configuration of a camera head and a camera control unit (CCU).

### MODES FOR CARRYING OUT THE INVENTION

A detailed description will be given below of embodiments of the present disclosure with reference to the drawings. It should be noted that the description will be given in the following order.

### 1. First Embodiment

In a first embodiment, a description will be given of an example where the present technology is applied to a solid-state imaging device.

### 2. Second Embodiment

In a second embodiment, a description will be given of an example where a plurality of amplifier transistors is provided with respect to one pixel circuit in the solid-state imaging device according to the first embodiment.

### 3. Third Embodiment

In a third embodiment, a description will be given of an example where a manner of bonding a first semiconductor layer and a second semiconductor layer to each other is changed in the solid-state imaging device according to the first embodiment.

### 4. Fourth Embodiment

In a fourth embodiment, a description will be given of an example where a planar shape of the pixel circuit is changed in the solid-state imaging device according to the first embodiment.

### 5. Fifth Embodiment

In a fifth embodiment, a description will be given of a modification example of an arrangement layout of transistors of the pixel circuit in the solid-state imaging device according to the first embodiment.

### 6. Sixth Embodiment

In a sixth embodiment, a description will be given of an example where a crystal orientation of the second semiconductor layer, in which the pixel circuit is provided, is changed in the solid-state imaging device according to the third embodiment.

### 7. Seventh Embodiment

In a seventh embodiment, a description will be given of an example where a capacitor is provided in the second semiconductor layer in the solid-state imaging device according to the first embodiment.

### 8. Eighth Embodiment

In an eighth embodiment, a description will be given of an example where a resistor is provided in the second semiconductor layer in the solid-state imaging device according to the first embodiment.

### 9. Ninth Embodiment

In a ninth embodiment, a description will be given of an example where a memory element is provided in the second semiconductor layer in the solid-state imaging device according to the first embodiment.

### 10. Application Example to Mobile Body

A description will be given of an example where the present technology is applied to a vehicle control system that is an example of a mobile body control system.

### 11. Application Example to Endoscopic Surgery System

A description will be given of an example where the present technology is applied to an endoscopic surgery system.

### 12. Other Embodiments

### 1. First Embodiment

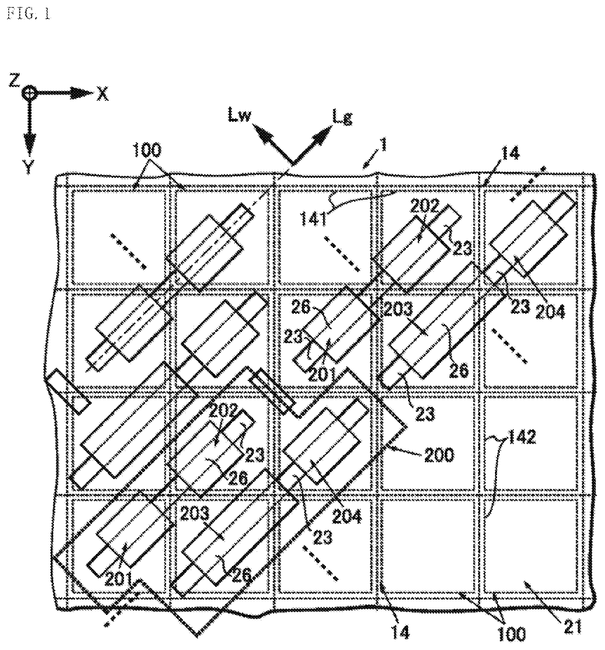

With use of FIG. 1 to FIG. 3, a description will be given of a solid-state imaging device 1 according to the first embodiment of the present disclosure.

Here, an arrow X direction indicated in the figures, if necessary, represents one planar direction of the solid-state imaging device 1 placed on a flat surface for the purpose of convenience. An arrow Y direction represents another planar direction orthogonal to the arrow X direction. In addition, an arrow Z direction represents an upper direction orthogonal to the arrow X direction and the arrow Y direction. That is, the arrow X direction, the arrow Y direction, and the arrow Z direction exactly correspond to an X-axis direction, a Y-axis direction, and a Z-axis direction of a three-dimensional coordinate system, respectively.

It should be noted that these directions are indicated for illustrative purpose only and not intended to limit directions according to the present technology.

### [Configuration of Solid-State Imaging Device 1]

(1) Circuit Configuration of Pixels 100 and Pixel Circuit 200 of Solid-State Imaging Device 1

FIG. 3 illustrates an example of a circuit configuration of pixels 100 and a pixel circuit 200 that constitute a solid-state imaging device 1.

One pixel 100 includes a series circuit including a photoelectric converter (a photodiode) 101 and a transfer transistor 102.

An anode terminal of the photoelectric converter 101 is coupled to a reference potential GND, and a cathode terminal thereof is coupled to one terminal of the transfer transistor 102. The photoelectric converter 101 converts light incoming from outside the solid-state imaging device 1 to an electric signal.

Another terminal of the transfer transistor 102 is coupled to the pixel circuit 200. A control terminal of the transfer transistor 102 is coupled to a horizontal signal line 103.

The pixel circuit 200 includes a floating diffusion (FD) conversion gain switching transistor 201, a reset transistor 202, an amplifier transistor 203, and a selection transistor 204.

The other terminal of the transfer transistor 102 is coupled to one terminal of the FD conversion gain switching transistor 201 and a control terminal of the amplifier transistor 203. Another terminal of the FD conversion gain switching transistor 201 is coupled to one terminal of the reset transistor 202. Another terminal of the reset transistor 202 is coupled to a power source potential VDD. One terminal of the amplifier transistor 203 is coupled to one terminal of the selection transistor 204. Another terminal of the amplifier transistor 203 is coupled to the power source potential VDD. Another terminal of the selection transistor 204 is coupled to a vertical signal line 205.

In the solid-state imaging device 1 according to the first embodiment, one pixel circuit 200 is provided for four pixels 100.

(2) Vertical Cross-Sectional Configuration of Solid-State Imaging Device 1

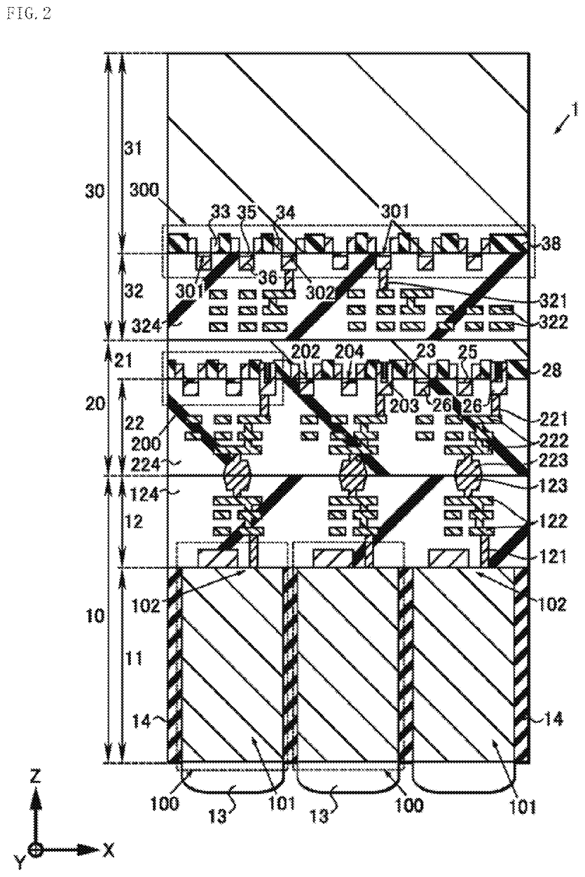

FIG. 2 illustrates an example of a vertical cross-sectional configuration of the solid-state imaging device 1.

Here, the solid-state imaging device 1 is configured as a back-illuminated image sensor. The solid-state imaging device 1 includes a first base 10, a second base 20, and a third base 30 that are stacked in order as seen in the arrow Y direction (hereinafter, simply referred to as “in a side view”). That is, the second base 20 is stacked on the first base 10, and the second base 20 is bonded to the first base 10. The third base 30 is stacked on the second base 20, and the third base 30 is bonded to the second base 20.

The first base 10 includes a first semiconductor layer 11 and a first wiring layer 12 provided on a side of the first semiconductor layer 11 toward the second base 20. The first semiconductor layer 11 includes monocrystalline silicon (Si).

The pixels 100 are provided in the first semiconductor layer 11. The photoelectric converter 101 of each of the pixels 100 includes an n-type semiconductor region and a p-type semiconductor region and includes a pn junction of them. A detailed structure of the photoelectric converter 101 is omitted.

A light receiving lens 13 is provided on a light-incoming side of the photoelectric converter 101 with an unillustrated charge fixing film and an unillustrated insulation film interposed therebetween. The light receiving lens 13 is provided for each of the pixels 100. The light receiving lens 13 is configured to concentrate light entering the photoelectric converter 101. Here, the light-incoming side is the opposite side to the side of the first semiconductor layer 11 toward the second base 20.

The transfer transistor 102 of each of the pixels 100 is provided on a surface portion on the side of the first semiconductor layer 11 toward the second base 20. A detailed structure of the transfer transistor 102 is also omitted. The transfer transistor 102 includes an n-channel insulated gate field effect transistor (IGFET: Insulated Gate Field Effect Transistor). The transfer transistor 102 includes paired main electrodes (terminals), a channel formation region, a gate insulation film, and a gate electrode (the control terminal). The paired main electrodes are a source region and a drain region.

Here, the IGFET includes at least a metal body/oxide film/semiconductor field effect transistor (MOSFET: Metal Oxide Semiconductor Field Effect Transistor) and a metal body/insulation body/semiconductor field effect transistor (MISFET: Metal Insulator Semiconductor Field Effect Transistor).

In addition, a pixel isolation region 14 is provided between adjacent ones of the pixels 100. The pixel isolation region 14 optically and electrically separates the adjacent ones of the pixels 100 from each other.

It should be noted that each of an arrangement layout of the pixels 100 and an arrangement layout of the pixel isolation region 14 will be described later in detail together with arrangement layouts of the amplifier transistor 203, etc. constituting the pixel circuit 200.

The first wiring layer 12 includes a wiring line 121, a multilayer wiring line 122, a first terminal 123, and an insulation body 124.

One end of the wiring line 121 is coupled to the transfer transistor 102 and another end of the wiring line 121 is coupled to the multilayer wiring line 122. The wiring line 121 is configured as a penetrating wiring line penetrating the first wiring layer 12 in a thickness direction, and includes, for example, a wiring line material such as tungsten (W).

Although not limited in the number of layers, the multilayer wiring line 122 includes a three-layer wiring line structure. Wiring lines of layers of the multilayer wiring line 122 are coupled through a coupling hole. The multilayer wiring line 122 includes, for example, a wiring line material such as aluminum (Al).

One end of the first terminal 123 is coupled to the multilayer wiring line 122, and another end of the first terminal 123 is provided to be exposed on a surface of the first wiring layer 12 on the side toward the second base 20. The first terminal 123 includes, for example, copper (Cu).

The insulation body 124 is provided to cause each of the wiring line 121, the multilayer wiring line 122, and the first terminal 123 to be embedded therein. The insulation body 124 actually includes a stack of a plurality of layers of insulation films. The insulation body 124 includes a silicon oxide film (SiO), a silicon nitride film (SiN), or a combination of them.

The second base 20 includes a second semiconductor layer 21 and a second wiring layer 22 provided on a side of the second semiconductor layer 21 toward the first base 10. The second semiconductor layer 21 includes monocrystalline silicon.

The pixel circuit 200 is provided in the second semiconductor layer 21. In other words, the second semiconductor layer 21 includes the FD conversion gain switching transistor 201, the reset transistor 202, the amplifier transistor 203, and the selection transistor 204 (see FIG. 3). The FD conversion gain switching transistor 201, the reset transistor 202, the amplifier transistor 203, and the selection transistor 204 constituting the pixel circuit 200 each correspond to a “first transistor” according to the present technology.

The pixel circuit 200 is provided in a principal surface portion of the second semiconductor layer 21 on the side toward the first base 10. Here, the principal surface portion is used to refer to a main surface part where a transistor, a capacitor, a resistor, and the like are provided.

The reset transistor 202 is provided in the principal surface portion of the second semiconductor layer 21 within a region surrounded by an element isolation region 28. A structure is not limited to a particular one; however, the element isolation region 28 having a trench structure is used here to improve a degree of integration.

The reset transistor 202 includes paired main electrodes 23, a channel formation region, a gate insulation film 25, and a gate electrode 26. The paired main electrodes 23 are a source region and a drain region, and include an n-type semiconductor region. The channel formation region includes the second semiconductor layer 21 between the paired main electrodes 23. The gate insulation film 25 is provided along the channel formation region, and includes, for example, a silicon oxide film, a silicon nitride film, or a stacked film of them. The gate electrode 26 is provided along the gate insulation film 25, and includes, for example, polycrystalline silicon. Similarly to the transfer transistor 102, the reset transistor 202 includes an n-channel IGFET.

Here, a gate lengthwise direction of the first transistor according to the present technology, which includes the reset transistor 202, is a direction in which a carrier flows between the paired main electrodes 23 and is a direction identical to a channel lengthwise direction.

The selection transistor 204 is provided in the principal surface portion of the second semiconductor layer 21 within the region surrounded by the element isolation region 28, as with the reset transistor 202. The selection transistor 204 includes paired main electrodes 23, a channel formation region, a gate insulation film 25, and a gate electrode 26. The selection transistor 204 includes an n-channel IGFET.

Although the illustration is omitted in FIG. 2, the FD conversion gain switching transistor 201 is provided in the principal surface portion of the second semiconductor layer 21 within the region surrounded by the element isolation region 28, as with the reset transistor 202 (see FIG. 1). The FD conversion gain switching transistor 201 includes paired main electrodes 23, a channel formation region, a gate insulation film 25, and a gate electrode 26. The FD conversion gain switching transistor 201 includes an n-channel IGFET.

The amplifier transistor 203 is provided in the principal surface portion of the second semiconductor layer 21 within the region surrounded by the element isolation region 28, as with the reset transistor 202. The amplifier transistor 203 includes paired main electrodes 23, a channel formation region, a gate insulation film 25, and a gate electrode 26. The amplifier transistor 203 includes an n-channel IGFET.

Here, the amplifier transistor 203 includes a fin-shaped structure. The fin-shaped structure is a structure where both end portions in a gate widthwise direction of the gate electrode 26 (and the gate insulation film 25) are extended in a depth direction from a principal surface of the second semiconductor layer 21 with a gate width dimension being expanded in the depth direction. Employing the fin-shaped structure makes it possible to increase a current amount of the amplifier transistor 203.

The second wiring layer 22 includes a wiring line 221, a multilayer wiring line 222, a second terminal 223, and an insulation body 224.

One end of the wiring line 221 is coupled to the amplifier transistor 203 and another end of the wiring line 221 is coupled to the multilayer wiring line 222. The wiring line 221 is configured as a penetrating wiring line penetrating the second wiring layer 22 in the thickness direction, as with the wiring line 121.

Although not limited in the number of layers, the multilayer wiring line 222 includes a three-layer wiring line structure, as with the multilayer wiring line 122.

One end of the second terminal 223 is coupled to the multilayer wiring line 222 and another end of the second terminal 223 is provided to be exposed on a surface of the second wiring layer 22 on the side toward the first base 10, as with the first terminal 123. The second terminal 223 is provided at a position corresponding to the first terminal 123, and is bonded to the first terminal 123 and electrically coupled thereto.

The insulation body 224 is provided to cause each of the wiring line 221, the multilayer wiring line 222, and the second terminal 223 to be embedded therein. The insulation body 224 includes a material similar to that of the insulation body 124.

In the solid-state imaging device 1 according to the first embodiment, the first terminal 123 of the first base 10 and the second terminal 223 of the second base 20 face each other to be bonded to each other. In other words, the first base 10 and the second base 20 are coupled to each other by a face-to-face (Face to Face) coupling structure.

The third base 30 includes a third semiconductor layer 31 and a third wiring layer 32 provided on a side of the third semiconductor layer 31 toward the second base 20. The third semiconductor layer 31 includes monocrystalline silicon.

A peripheral circuit 300 that controls an operation of the pixel circuit 200 is provided in the third semiconductor layer 31. Although the detailed description is omitted, the peripheral circuit 300 includes, for example, an input section, a timing controller, a row driver, a column signal processor, an image signal processor, and an output section. The peripheral circuit 300 includes a complementary IGFET including an n-channel IGFET 301 and a p-channel IGFET 302. The complementary IGFET corresponds to a “second transistor” according to the present technology.

The n-channel IGFET 301 is provided in a principal surface portion of the third semiconductor layer 31 within a region surrounded by an element isolation region 38. A trench structure is applied to the element isolation region 38, as with the element isolation region 28.

The n-channel IGFET 301 includes paired main electrodes 33, a channel formation region, a gate insulation film 35, and a gate electrode 36. The paired main electrodes 33 are a source region and a drain region, and include an n-type semiconductor region. The channel formation region includes the third semiconductor layer 31 between the paired main electrodes 33. The gate insulation film 35 is provided along the channel formation region, and includes, for example, a material similar to that of the gate insulation film 25. The gate electrode 36 is provided along the gate insulation film 35, and includes, for example, a material similar to that of the gate electrode 26.

The p-channel IGFET 302 includes paired main electrodes 34, a channel formation region, a gate insulation film 35, and a gate electrode 36. The paired main electrodes 34 are a source region and a drain region, and include a p-type semiconductor region. The channel formation region includes the third semiconductor layer 31 between the paired main electrodes 34.

It should be noted that although the illustration is omitted, the n-channel IGFET 301 is provided in a p-type well region in the principal surface portion of the third semiconductor layer 31. The p-channel IGFET 302 is provided in an n-type well region provided in the principal surface portion of the third semiconductor layer 31.

The third wiring layer 32 includes a wiring line 321, a multilayer wiring line 322, and an insulation body 324.

One end of the wiring line 321 is coupled to the complementary IGFET, and another end of the wiring line 321 is coupled to the multilayer wiring line 322. The wiring line 321 is configured as a penetrating wiring line penetrating the third wiring layer 32 in the thickness direction, as with the wiring line 121.

Although not limited in the number of layers, the multilayer wiring line 322 includes a three-layer wiring line structure, as with the multilayer wiring line 122. The multilayer wiring line 322 is coupled to the multilayer wiring line 222 of the second base 20 through an unillustrated penetrating wiring line.

The insulation body 324 is provided to cause each of the wiring line 321 and the multilayer wiring line 322 to be embedded therein. The insulation body 324 includes a material similar to that of the insulation body 124.

(3) Planar Configuration of Pixels 100 and Pixel Circuit 200

FIG. 1 illustrates an example of an arrangement layout of the pixels 100 and an arrangement layout of the pixel circuit 200 as the solid-state imaging device 1 is viewed in the arrow Z direction from the light-incoming side (hereinafter, simply referred to as a “plan view”).

The plurality of pixels 100 is arranged in a matrix along a plane direction parallel with a surface of the first semiconductor layer 11 of the first base 10. That is, the pixels 100 are arranged at regular intervals in the arrow X direction and the arrow Y direction. The respective pixel isolation region 14 is provided between ones of the pixels 100 adjacent in the arrow X direction and between ones of the pixels 100 adjacent in the arrow Y direction. In the first embodiment, the pixels 100 each have a rectangular shape in a plan view, more particularly, a square shape.

In the pixel circuit 200, the FD conversion gain switching transistor 201 and the reset transistor 202 are disposed in line along the principal surface of the second semiconductor layer 21 with respective gate lengthwise directions thereof being aligned. Here, the gate lengthwise direction is an arrow direction labelled with a reference sign “Lg”. In addition, the gate widthwise direction is an arrow direction labelled with a reference sign “Lw”. One of the main electrodes 23 of the FD conversion gain switching transistor 201 is formed integrally with one of the main electrodes 23 of the reset transistor 202. The gate lengthwise directions of the FD conversion gain switching transistor 201 and the reset transistor 202 are inclined with respect to an arrangement direction of the pixels 100 (the arrow X direction or the arrow Y direction). In the first embodiment, the FD conversion gain switching transistor 201 and the reset transistor 202 are provided with the gate lengthwise directions in alignment with diagonal directions of the rectangular shapes of the pixels 100, that is, with the gate lengthwise directions being parallel with the diagonal directions of the rectangular shapes of the pixels 100.

In addition, in the pixel circuit 200, the amplifier transistor 203 and the selection transistor 204 are disposed in line along the principal surface of the second semiconductor layer 21 with respective gate lengthwise directions thereof being aligned. One of the main electrodes 23 of the amplifier transistor 203 is formed integrally with one of the main electrodes 23 of the selection transistor 204. The gate lengthwise directions of the amplifier transistor 203 and the selection transistor 204 are inclined with respect to the arrangement direction of the pixels 100 (the arrow X direction or the arrow Y direction), as with those of the FD conversion gain switching transistor 201 and the reset transistor 202. The amplifier transistor 203 and the selection transistor 204 are spaced in the gate widthwise direction with respect to the FD conversion gain switching transistor 201 and the reset transistor 202, while the gate lengthwise direction of the amplifier transistor 203 and the selection transistor 204 are parallel with those of the FD conversion gain switching transistor 201 and the reset transistor 202.

Further, one pixel circuit 200 is provided for four pixels 100. The FD conversion gain switching transistor 201 of the one pixel circuit 200 is provided with the gate lengthwise direction being aligned with a diagonal direction of one of the four pixels 100. Likewise, the reset transistor 202 of the one pixel circuit 200 is disposed with the gate lengthwise direction being aligned with a diagonal direction of one of the four pixels 100. The amplifier transistor 203 of the one pixel circuit 200 is disposed with the gate lengthwise direction being aligned with a diagonal direction of one of the four pixels 100. Further, the selection transistor 204 of the one pixel circuit 200 is disposed with the gate lengthwise direction being aligned with a diagonal direction of one of the four pixels 100.

Here, a dimension of one side of one pixel 100 is set, for example, in a range from 0.4 μm to 2.0 μm both inclusive; however, these numeral values are not limiting. Meanwhile, a gate length dimension of each of the FD conversion gain switching transistor 201, the reset transistor 202, and the selection transistor 204 of the pixel circuit 200 is set, for example, in a range from 150 nm to 300 nm both inclusive. Further, a gate length dimension of the amplifier transistor 203 is longer than, for example, the gate length dimension of the reset transistor 202 or the like, and is set, for example, in a range from 300 nm to 600 nm both inclusive.

In addition, as expressed in another way, the pixel isolation region 14 is provided between the pixels 100 and, in a plan view, the pixel isolation region 14 has a grid shape. That is, the pixel isolation region 14 includes first partition walls 141 extending in the arrow X direction and disposed at regular intervals in the arrow Y direction, and includes second partition walls 142 extending in the arrow Y direction and disposed at regular intervals in the arrow X direction. Thus, the gate lengthwise direction of the FD conversion gain switching transistor 201 or the like of the pixel circuit 200 is inclined with respect to an extending direction of the first partition wall 141 or the second partition wall 142.

Here, although the illustration is omitted, the respective gate lengthwise directions of the n-channel IGFET 301 and the p-channel IGFET 302, which constitute the peripheral circuit 300, are parallel with the arrangement direction of the pixels 100.

### [Workings and Effects]

The solid-state imaging device 1 according to the first embodiment includes the first semiconductor layer 11 and the second semiconductor layer 21 as illustrated in FIG. 2. As illustrated in FIG. 1, the pixel 100 is arranged in a matrix along the plane direction in the first semiconductor layer 11. The pixel 100 includes the photoelectric converter 101. The number of the pixel 100 is two or more. The second semiconductor layer 21 is stacked on the first semiconductor layer 11 on the opposite side to the light-incoming side of the pixel 100. The first transistor is provided in the second semiconductor layer 21. The first transistor is electrically coupled to the pixel 100 and has the gate lengthwise direction inclined with respect to the arrangement direction of the pixel 100. The first transistor includes the FD conversion gain switching transistor 201, the reset transistor 202, the amplifier transistor 203, or the selection transistor 204 constituting the pixel circuit 200.

The pixel 100 is disposed in the first semiconductor layer 11, and the first transistor is provided in the second semiconductor layer 21 independently of the pixel 100. This makes it possible to secure an area to dispose the first transistor in the second semiconductor layer 21 even though the number of the arranged pixels 100 increases with minimization of the pixel 100.

Additionally, the gate lengthwise direction of the first transistor is inclined with respect to the arrangement direction of the pixel 100, which makes it possible to increase the gate length dimension of the first transistor. This makes it possible to effectively suppress or prevent the occurrence of a short-channel effect or the occurrence of noise in the first transistor and, consequently, improve electrical properties of the first transistor. In particular, it is possible to effectively suppress or prevent the occurrence of RTS (Random Telegraph Signal) noise in the amplifier transistor 203 serving as the first transistor. Therefore, it is possible to improve electrical properties of the pixel circuit 200.

Further additionally, the gate lengthwise direction of the first transistor is inclined with respect to the arrangement direction of the pixel 100, which makes it possible to expand the gate width dimension of the first transistor. In particular, it is possible to expand the respective gate width dimensions of the amplifier transistor 203 and the selection transistor 204. This makes it possible to improve transconductance (gm) of each of the amplifier transistor 203 and the selection transistor 204 and, consequently, effectively suppress or prevent thermal noise. In addition, an improvement in the transconductance enables speeding up an operation speed of the pixel circuit 200.

In addition, in the solid-state imaging device 1, the pixel 100 has a rectangular shape in a plan view as illustrated in FIG. 1. Further, the gate lengthwise direction of the first transistor is parallel with the diagonal direction of the pixel 100 in a plan view. This makes it possible to maximize the gate length dimension of the first transistor.

Specifically, the gate length dimension of the first transistor is allowed to be approximately 1.4 times longer than that in a case where the gate lengthwise direction is parallel with the arrangement direction of the pixel 100. Therefore, it is possible to further improve the electrical properties of the first transistor.

Further, in the solid-state imaging device 1, the first transistor constitutes the pixel circuit 200 coupled to the pixel 100 as illustrated in FIG. 3. That is, the pixel 100 is provided in the first semiconductor layer 11, and the pixel circuit 200 is provided in the second semiconductor layer 21, as illustrated in FIG. 2. This makes it possible to miniaturize the pixel 100 and increase the number of the arranged pixels 100 independently of an area to dispose the pixel circuit 200.

In addition, in the solid-state imaging device 1, the gate length dimension of the amplifier transistor 203 serving as the first transistor is longer than the gate length dimension of the selection transistor 204 or the reset transistor 202 as illustrated in FIG. 1. This makes it possible to more effectively suppress or prevent the occurrence of RTS noise in the amplifier transistor 203 and, consequently, further improve the electrical properties.

Further, the solid-state imaging device 1 includes the first terminal 123 and the second terminal 223 as illustrated in FIG. 2. The first terminal 123 is provided on a side of the first semiconductor layer 11 toward the second semiconductor layer 21 and is electrically coupled to the pixel 100 via the first wiring layer 12. The second terminal 223 is provided on a side of the second semiconductor layer 21 toward the first semiconductor layer 11, is electrically coupled to the first transistor via the second wiring layer 22, and is bonded to the first terminal 123. That is, the first base 10 including the first semiconductor layer 11 and the second base 20 including the second semiconductor layer 21 are coupled to each other by the face-to-face coupling structure. In the face-to-face coupling structure, the second wiring layer 222 is provided in a coupling path between the second terminal 223 and the first transistor in a coupling path between the pixel 100 and the first transistor.

This makes it possible to route the wiring line in the second wiring layer 22 and, consequently, freely lay out a position to dispose the first transistor.

In addition, the solid-state imaging device 1 includes the third semiconductor layer 31 as illustrated in FIG. 2. The third semiconductor layer 31 is stacked on the opposite side of the second semiconductor layer 21 to the first semiconductor layer 11. The third semiconductor layer 31 includes the second transistor, and the second transistor constitutes the peripheral circuit 300 that controls the pixel circuit 200. The second transistor is, for example, a complementary IGFET. That is, the pixel 100 is provided in the first semiconductor layer 11, the pixel circuit 200 is provided in the second semiconductor layer 21, and the peripheral circuit 300 is provided in the third semiconductor layer 31.

This makes it possible to arrange mainly the pixel 100 in the first semiconductor layer 11 and, consequently, increase the number of the arranged pixels 100.

Further, in the solid-state imaging device 1, the gate lengthwise direction of the second transistor illustrated in FIG. 2 is parallel with the arrangement direction of the pixel 100. As expressed in another way, the gate lengthwise direction of the first transistor, which constitutes the pixel circuit 200, is inclined with respect to the gate lengthwise direction of the second transistor.

This makes it possible to achieve optimization of the electrical properties of the first transistor independently of the second transistor.

### 2. Second Embodiment

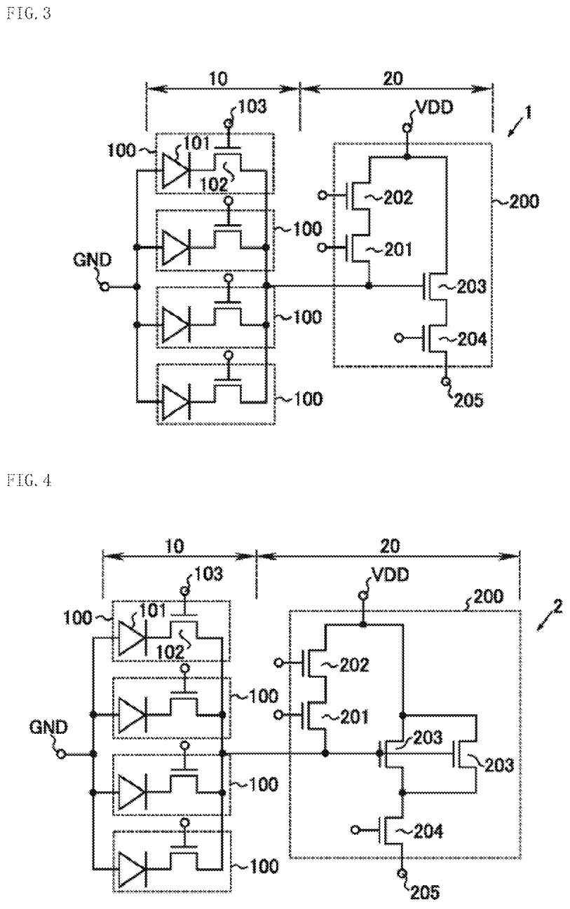

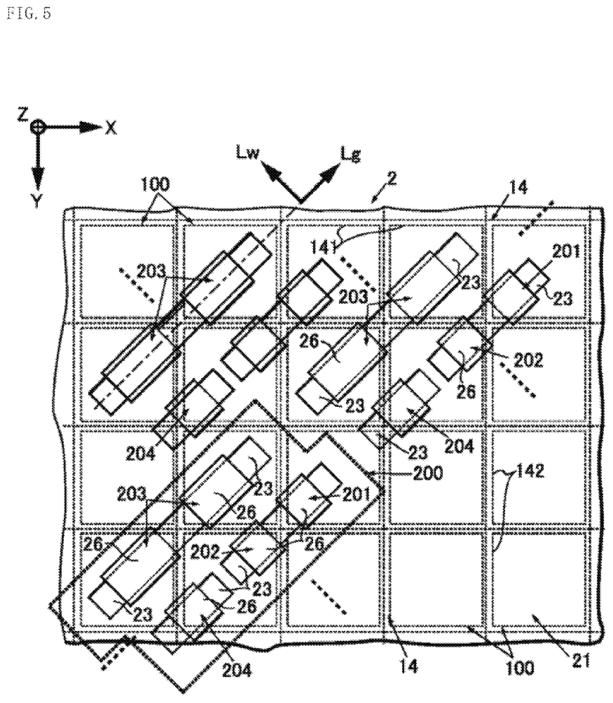

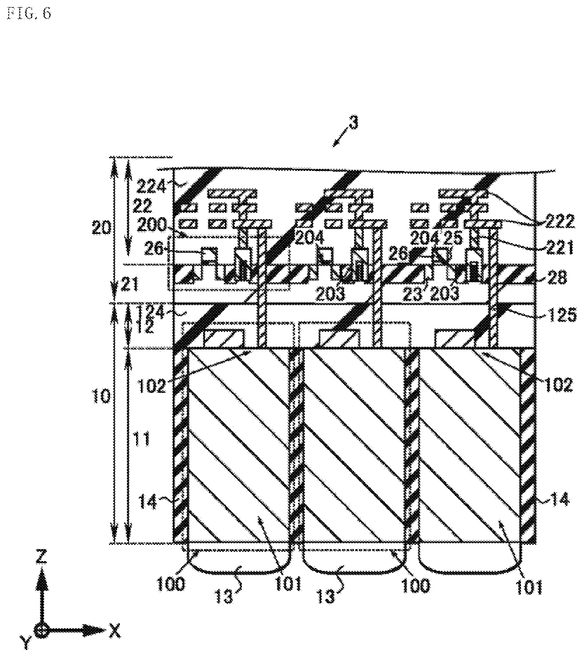

With use of FIG. 4 and FIG. 5, a description will be given of a solid-state imaging device 2 according to the second embodiment of the present disclosure. It should be noted that in the second embodiment and embodiments described thereafter, the same reference sign is used to refer to the same component or substantially the same component as the component of the solid-state imaging device 1 according to the first embodiment, and a redundant description thereof will be omitted.

### [Configuration of Solid-State Imaging Device 2]

FIG. 4 illustrates a circuit configuration of an example of the pixels 100 and the pixel circuit 200 that constitute the solid-state imaging device 2.

The pixel circuit 200 of the solid-state imaging device 2 according to the second embodiment includes the FD conversion gain switching transistor 201, the reset transistor 202, two amplifier transistors 203, and the selection transistor 204. That is, the two amplifier transistors 203 are provided for one pixel circuit 200. The two amplifier transistors 203 are electrically coupled in parallel.

FIG. 5 illustrates an example of an arrangement layout of the pixels 100 and an arrangement layout of the pixel circuit 200 of the solid-state imaging device 2 in a plan view.

In the pixel circuit 200, the FD conversion gain switching transistor 201 and the reset transistor 202 are disposed in line along the principal surface of the second semiconductor layer 21 with respective gate lengthwise directions thereof being aligned. One of the main electrodes 23 of the FD conversion gain switching transistor 201 is formed integrally with one of the main electrodes 23 of the reset transistor 202. The gate lengthwise directions of the FD conversion gain switching transistor 201 and the reset transistor 202 are inclined with respect to an arrangement direction of the pixels 100. In the second embodiment, the FD conversion gain switching transistor 201 and the reset transistor 202 are each provided with the gate lengthwise direction being aligned with the diagonal direction of the rectangular shape of the pixel 100, as in the solid-state imaging device 1 according to the first embodiment.

The selection transistor 204 is disposed with the gate lengthwise direction being aligned on extensions in the gate lengthwise directions of the FD conversion gain switching transistor 201 and the reset transistor 202.

In addition, in the pixel circuit 200, the two amplifier transistors 203 are disposed in line along the principal surface of the second semiconductor layer 21 with respective gate lengthwise directions thereof being aligned. Respective ones of the main electrodes 23 of the two amplifier transistors 203 are integrally formed. The gate lengthwise directions of the two amplifier transistors 203 are inclined with respect to the arrangement direction of the pixels 100, as with those of the FD conversion gain switching transistor 201, the reset transistor 202, and the selection transistor 204. The two amplifier transistors 203 are spaced in the gate widthwise direction with respect to the FD conversion gain switching transistor 201, the reset transistor 202, and the selection transistor 204, while the gate lengthwise directions of the two amplifier transistors 203 are parallel with those of the FD conversion gain switching transistor 201, the reset transistor 202, and the selection transistor 204.

The components other than the above-described pixel circuit 200 are the same as the components of the solid-state imaging device 1 according to the first embodiment.

### [Workings and Effects]

The solid-state imaging device 2 according to the second embodiment makes it possible to achieve workings and effects similar to the workings and effects achievable by the solid-state imaging device 1 according to the first embodiment.

In addition, in the solid-state imaging device 2, the plurality of amplifier transistors 203 is electrically coupled in parallel with respect to one pixel circuit 200 as illustrated in FIG. 4 and FIG. 5. Here, the two amplifier transistors 203 are electrically coupled in parallel. This makes it possible to more effectively suppress or prevent the occurrence of RTS noise in the amplifier transistors 203 and, consequently, further improve the electrical properties.

### 3. Third Embodiment

With use of FIG. 6, a description will be given of a solid-state imaging device 3 according to the third embodiment of the present disclosure.

### [Configuration of Solid-State Imaging Device 3]

FIG. 6 illustrates an example of a vertical cross-sectional configuration of a main part representing the pixels 100 and the pixel circuit 200 of the solid-state imaging device 3.

The solid-state imaging device 3 according to the third embodiment includes the first base 10, the second base 20, and the unillustrated third base 30 that are stacked in order in a side view, as with the solid-state imaging device 1 according to the first embodiment. Here, the second base 20 includes the second semiconductor layer 21 provided on a side toward the first base 10 and the second wiring layer 22 provided on a side toward the third base 30. The principal surface of the second semiconductor layer 21 is defined on the side toward the third base 30, and the amplifier transistor 203 and the like constituting the pixel circuit 200 (see FIG. 3 or FIG. 4) are provided in the principal surface portion of the second semiconductor layer 21.

The pixel 100 and the pixel circuit 200 are electrically coupled to each other via the penetrating wiring line 125. One end of the penetrating wiring line 125 is coupled to the transfer transistor 102 of the pixel 100. Another end of the penetrating wiring line 125 penetrates the second semiconductor layer 21 in the thickness direction and is coupled to the second wiring layer 22. The second wiring layer 22 is coupled to the amplifier transistor 203 and the unillustrated FD conversion gain switching transistor 201.

That is, the first base 10 and the second base 20 are coupled to each other by a face-to-back (Face to Back) coupling structure.

The components other than the above-described coupling structure are the same as the components of the solid-state imaging device 1 according to the first embodiment.

### [Workings and Effects]

The solid-state imaging device 3 according to the third embodiment makes it possible to achieve workings and effects similar to the workings and effects achievable by the solid-state imaging device 1 according to the first embodiment.

In addition, in the solid-state imaging device 3, the first base 10 including the first semiconductor layer 11 and the second base including the second semiconductor layer 21 are coupled to each other by the face-to-back coupling structure as illustrated in FIG. 6. Further, the pixel 100 and the pixel circuit 200 are coupled to each other via the penetrating wiring line 125.

This allows a length of a signal path coupling the pixel 100 and the pixel circuit 200 to each other to be short as compared with in, for example, the solid-state imaging device 1 according to the first embodiment. It is thus possible to reduce a signal-noise ratio (SN ratio:signal-noise ratio).

### 4. Fourth Embodiment

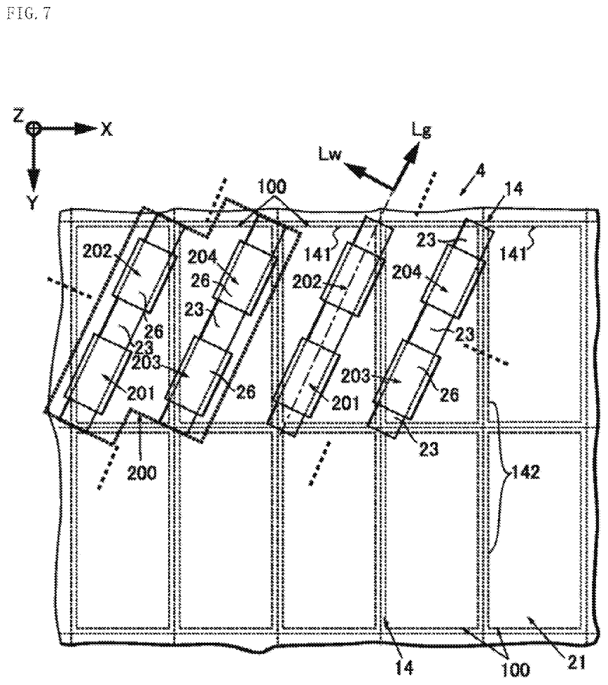

With use of FIG. 7, a description will be given of a solid-state imaging device 4 according to the fourth embodiment of the present disclosure.

### [Configuration of Solid-State Imaging Device 4]

FIG. 7 illustrates an example of an arrangement layout of the pixels 100 and an arrangement layout of the pixel circuit 200 of the solid-state imaging device 4.

In the solid-state imaging device 4 according to the fourth embodiment, the pixels 100 each have a quadrangular shape having longer sides parallel with the arrow Y direction than sides parallel with the arrow X direction in a plan view. Further, the first transistor such as the amplifier transistor 203 constituting the pixel circuit 200 is provided with the gate lengthwise direction being parallel with the diagonal direction of the pixel 100.

### [Workings and Effects]

The solid-state imaging device 4 according to the fourth embodiment makes it possible to achieve workings and effects similar to the workings and effects achievable by the solid-state imaging device 1 according to the first embodiment.

### 5. Fifth Embodiment

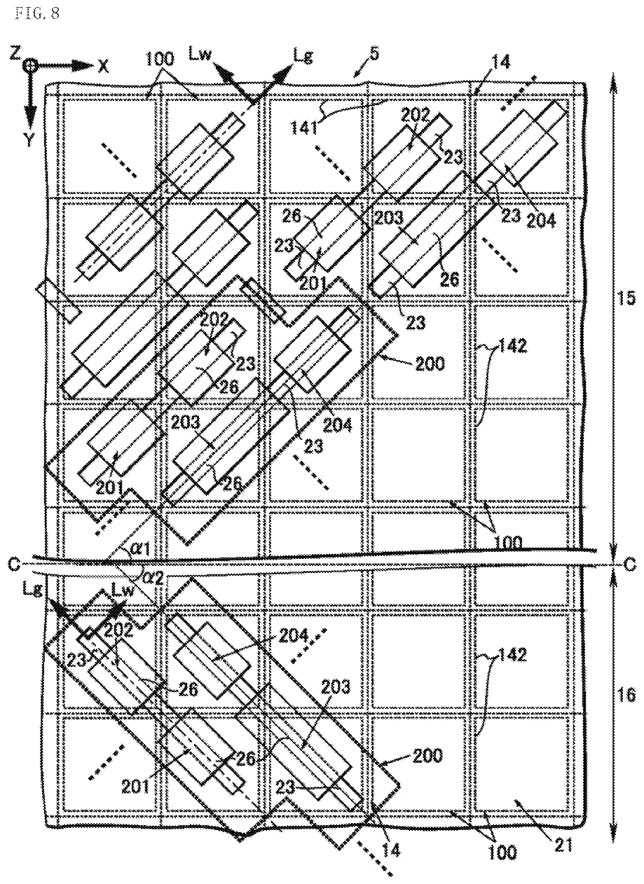

With use of FIG. 8, a description will be given of a solid-state imaging device 5 according to the fifth embodiment of the present disclosure.

### [Configuration of Solid-State Imaging Device 5]

FIG. 8 illustrates an example of an arrangement layout of the pixels 100 and an arrangement layout of the pixel circuit 200 of the solid-state imaging device 5.

The solid-state imaging device 5 according to the fifth embodiment includes a plurality of pixel regions in a plan view. Here, for the purpose of simplifying the description, the solid-state imaging device 5 includes two pixel regions, i.e., a first pixel region 15 and a second pixel region 16.

In the first pixel region 15, the first transistors are arranged, as in the solid-state imaging device 1 according to the first embodiment. That is to say, the FD conversion gain switching transistor 201, the reset transistor 202, the amplifier transistor 203, and the selection transistor 204, which constitute the pixel circuit 200, are arranged with the gate lengthwise directions being inclined with respect to the arrangement direction of the pixels 100. The gate lengthwise directions of the amplifier transistor 203 and the like are parallel with the diagonal directions of the pixels 100.

With reference to a boundary line C-C virtually set on a boundary between the first pixel region 15 and the second pixel region 16, the gate lengthwise directions of the amplifier transistor 203 and the like are set at an angle α1 in a counterclockwise direction. The angle α1 is 45 degrees here.

In the second pixel region 16, the FD conversion gain switching transistor 201, the reset transistor 202, the amplifier transistor 203, and the selection transistor 204, which constitute the pixel circuit 200, are arranged with the gate lengthwise directions being inclined with respect to the arrangement direction of the pixels 100. The gate lengthwise directions of the amplifier transistor 203 and the like are parallel with the diagonal directions of the pixels 100.

In the second pixel region 16, the gate lengthwise directions of the amplifier transistor 203 and the like are set at an angle α2 in a clockwise direction with reference to the boundary line C-C. The angle α2 is 45 degrees here.

That is to say, a gate lengthwise direction of the first pixel region 15 is set to be orthogonal to a gate lengthwise direction of the second pixel region 16. As expressed in another way, the gate lengthwise direction of the second pixel region 16 is parallel with a gate widthwise direction of the first pixel region 15.

### [Workings and Effects]

The solid-state imaging device 5 according to the fifth embodiment makes it possible to achieve workings and effects similar to the workings and effects achievable by the solid-state imaging device 1 according to the first embodiment.

### 6. Sixth Embodiment

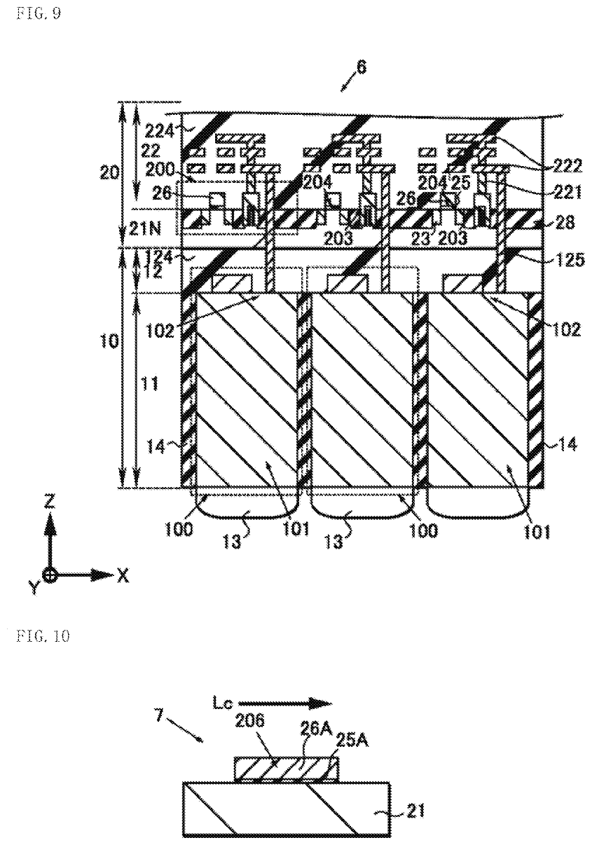

With use of FIG. 9, a description will be given of a solid-state imaging device 6 according to the sixth embodiment of the present disclosure.

### [Configuration of Solid-State Imaging Device 6]

FIG. 9 illustrates an example of a vertical cross-sectional configuration of a main part representing the pixels 100 and the pixel circuit 200 of the solid-state imaging device 6. Here, it is described as a modification example of the solid-state imaging device 3 according to the third embodiment.

The solid-state imaging device 6 according to the sixth embodiment includes a second semiconductor layer 21N in place of the second semiconductor layer 21 of the second base 20 of the solid-state imaging device 3 according to the third embodiment. The second semiconductor layer 21N is diced from a semiconductor wafer (a monocrystalline silicon substrate) having a 0 (zero)-degree notch that is used for a process to manufacture the solid-state imaging device 6. A side surface, of the second semiconductor layer 21N, at which dicing has been performed is a <110> crystal plane.

The amplifier transistor 203, which is provided in a principal surface portion of the second semiconductor layer 21N, employs a fin-shaped structure as described above with a gate lengthwise direction thereof being inclined by 45 degrees with respect to the arrangement direction of the pixels 100. This causes a side wall of a channel formation region (the second semiconductor layer 21N) of the amplifier transistor 203 to be set to a <100> crystal plane.

### [Workings and Effects]

The solid-state imaging device 6 according to the sixth embodiment makes it possible to achieve workings and effects similar to the workings and effects achievable by the solid-state imaging device 3 according to the third embodiment.

In addition, the solid-state imaging device 6 includes the second semiconductor layer 21N diced from the semiconductor wafer having the 0-degree notch. In the second semiconductor layer 21N, the amplifier transistor 203 employing the fin-shaped structure is provided with the gate lengthwise direction being parallel with the arrangement direction of the pixels 100.

This allows the side wall of the channel formation region of the amplifier transistor 203 to be the <100> crystal plane. In monocrystalline silicon, an interface state that causes noise to get worse is lower in the <100> crystal plane than in the <110> crystal plane. Therefore, it is possible to effectively suppress or prevent the noise of the amplifier transistor 203.

It should be noted that in the solid-state imaging device 1 according to the first embodiment, workings and effects similar to the workings and effects achievable by the solid-state imaging device 6 according to the sixth embodiment are achievable also in a case where the second semiconductor layer 21 is replaced by the second semiconductor layer 21N.

### 7. Seventh Embodiment

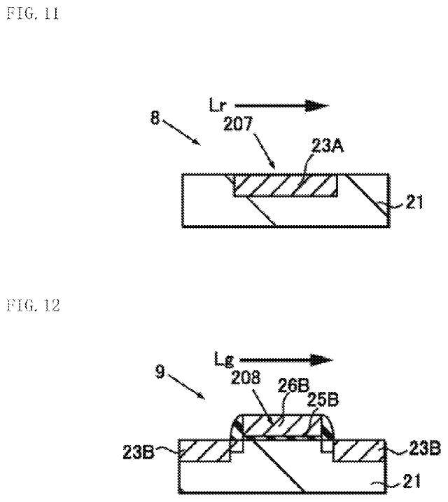

With use of FIG. 10, a description will be given of a solid-state imaging device 7 according to the seventh embodiment of the present disclosure.

### [Configuration of Solid-State Imaging Device 7]

FIG. 10 illustrates an example of a vertical cross-sectional configuration of a capacitor 206 to be mounted on the second base 20 of the solid-state imaging device 7.

The solid-state imaging device 7 includes the capacitor (a capacitor element) 206 within the pixel circuit 200 or in a region outside the pixel circuit 200 at the second semiconductor layer 21 of the second base 20. The capacitor 206 includes the second semiconductor layer 21 serving as a second electrode, a dielectric body 25A provided on the second semiconductor layer 21, and a metal body 26A serving as a first electrode and provided on the dielectric body 25A. That is to say, the capacitor 206 is configured as a metal body/dielectric body/semiconductor capacitor.

The second semiconductor layer 21 of the capacitor 206 includes monocrystalline silicon. The dielectric body 25A includes, for example, the same material as that of the gate insulation film 25 (see FIG. 2) of the selection transistor 204 or the like that constitutes the pixel circuit 200. The metal body 26A includes, for example, the same material as that of the gate electrode 26 of the selection transistor 204 or the like.

In a case where the dielectric body 25A includes silicon oxide, the capacitor 206 is configured as a MOS (Metal Oxide Semiconductor) capacitor. In contrast, in a case where the dielectric body 25A includes an insulation body other than silicon oxide, for example, silicon nitride, the capacitor 206 is configured as a MIS (Metal Insulator Semiconductor) capacitor.

Further, the capacitor 206 is provided at the second semiconductor layer 21 with a centerline Lc, which is along a plane direction of the metal body 26A, being parallel with, for example, the gate lengthwise direction of the selection transistor 204 or the like.

### [Workings and Effects]

The solid-state imaging device 7 according to the seventh embodiment makes it possible to achieve workings and effects similar to the workings and effects achievable by the solid-state imaging device according to the first embodiment.

In addition, the solid-state imaging device 7 includes the capacitor 206 at the second semiconductor layer 21 of the second base 20 as illustrated in FIG. 10. It is thus possible to effectively use the second semiconductor layer 21. For example, a circuit including the capacitor 206 is mountable on the second semiconductor layer 21.

Further, in the solid-state imaging device 7, the capacitor 206 is provided at the second semiconductor layer 21 with the centerline Lc of the metal body 26A, which serves as the first electrode, being parallel with the gate lengthwise direction of the selection transistor 204 or the like. This makes it possible to increase dimensions in a direction of the centerline Lc and a direction orthogonal to the centerline Lc to increase a capacitor area and, consequently, increase a capacitance value of the capacitor 206.

### 8. Eighth Embodiment

With use of FIG. 11, a description will be given of a solid-state imaging device 8 according to the eighth embodiment of the present disclosure.

### [Configuration of Solid-State Imaging Device 8]

FIG. 11 illustrates an example of a vertical cross-sectional configuration of a resistor 207 to be mounted on the second base 20 of the solid-state imaging device 8.

The solid-state imaging device 8 includes the resistor (a resistor element) 207 within the pixel circuit 200 or in a region outside the pixel circuit 200 at the second semiconductor layer 21 of the second base 20. The resistor 207 includes a semiconductor region (a diffusion layer) 23A provided in the principal surface portion of the second semiconductor layer 21. That is, the resistor 207 is a diffusion layer resistor.

The semiconductor region 23A includes, for example, the same structure as that of the main electrodes 23 of the selection transistor 204 or the like that constitutes the pixel circuit 200. Here, the semiconductor region 23A is an n-type semiconductor region.

Alternatively, the semiconductor region 23A may include a p-type semiconductor region, or an unillustrated p-type well region, or an unillustrated n-type well region.

Further, the resistor 207 may include, for example, the same material as that of the gate electrode 26 of the selection transistor 204 or the like. In a case where the gate electrode 26 includes, for example, polycrystalline silicon, the resistor 207 is a polysilicon resistor.

Further, the resistor 207 is provided in the second semiconductor layer 21 with a resistor lengthwise direction Lr being parallel with, for example, the gate lengthwise direction of the selection transistor 204 or the like.

### [Workings and Effects]

The solid-state imaging device 8 according to the eighth embodiment makes it possible to achieve workings and effects similar to the workings and effects achievable by the solid-state imaging device according to the first embodiment.

In addition, the solid-state imaging device 8 includes the resistor 207 at the second semiconductor layer 21 of the second base 20 as illustrated in FIG. 11. It is thus possible to effectively use the second semiconductor layer 21. For example, a circuit including the resistor 207 is mountable on the second semiconductor layer 21.

Further, in the solid-state imaging device 8, the resistor 207 is provided at the second semiconductor layer 21 with the resistor lengthwise direction Lr being parallel with the gate lengthwise direction of the selection transistor 204 or the like. This makes it possible to increase a resistor length dimension of the resistor 207 and, consequently, increase a resistance value of the resistor 207.

It should be noted that the solid-state imaging device 8 according to the eighth embodiment may be combined with the solid-state imaging device 7 according to the seventh embodiment to provide the second semiconductor layer 21 with the resistor 207 and the capacitor 206.

### 9. Ninth Embodiment

With use of FIG. 12, a description will be given of a solid-state imaging device 9 according to the ninth embodiment of the present disclosure.

### [Configuration of Solid-State Imaging Device 9]

FIG. 12 illustrates an example of a vertical cross-sectional configuration of a memory element 208 to be mounted on the second base 20 of the solid-state imaging device 9.

The solid-state imaging device 9 includes the memory element 208 within the pixel circuit 200 or in a region outside the pixel circuit 200 at the second semiconductor layer 21 of the second base 20. In the ninth embodiment, the memory element 208 is a memory cell employing one transistor structure of a ferroelectric memory (FeRAM: Ferroelectric Random Access Memory). In addition, although only the single memory element 208 is illustrated, a plurality of memory elements 208 is actually arranged in a matrix.

The memory element 208 includes paired main electrodes 23B, a channel formation region, a ferroelectric body 25B, and a gate electrode 26B. The paired main electrodes 23B are a source region and a drain region.

The main electrodes 23B include, for example, the same structure as that of the main electrodes 23 of the selection transistor 204 or the like that constitutes the pixel circuit 200. That is, the main electrodes 23B are n-type semiconductor regions. It should be noted that a side wall spacer, a reference sign of which is omitted, is provided on a side wall of the gate electrode 26B. The side wall spacer is used to provide the main electrodes 23B to have an LDD (Lightly Doped Drain) structure.

The channel formation region includes the second semiconductor layer 21 between the paired main electrodes 23B.

The ferroelectric body 25B is provided on the channel formation region. The ferroelectric body 25B includes a high-kappa (High-K) insulation body that is higher in dielectric constant than, for example, silicon dioxide. Specifically, the ferroelectric body 25B includes, for example, zirconium hafnium oxide (HfZrO), zirconium oxide (ZrO), hafnium oxide (HfO), or the like.

The gate electrode 26B is provided on the ferroelectric body 25B. The gate electrode 26B includes, for example, the same material as that of the gate electrode 26 of the selection transistor 204 or the like.

Further, the memory element 208 is provided in the second semiconductor layer 21 with a gate lengthwise direction of the memory element 208 being parallel with the gate lengthwise direction of the selection transistor 204 or the like.

### [Workings and Effects]

The solid-state imaging device 9 according to the ninth embodiment makes it possible to achieve workings and effects similar to the workings and effects achievable by the solid-state imaging device according to the first embodiment.

In addition, the solid-state imaging device 9 includes the memory element 208 on the second semiconductor layer 21 of the second base 20 as illustrated in FIG. 12. It is thus possible to effectively use the second semiconductor layer 21. For example, a circuit including a ferroelectric memory is mountable on the second semiconductor layer 21.

Further, in the solid-state imaging device 9, the memory element 208 is provided in the second semiconductor layer 21 with the gate lengthwise direction of the memory element 208 being parallel with the gate lengthwise direction of the selection transistor 204 or the like that constitutes the pixel circuit 200 (see FIG. 1). This makes it possible to effectively suppress or prevent the occurrence of a short-channel effect or noise in the memory element 208 and, consequently, improve electrical reliability.

Additionally, it is possible to expand a dimension of the memory element 208 in the gate widthwise direction, and therefore possible to improve transconductance.

It should be noted that the solid-state imaging device 9 according to the ninth embodiment may be combined with the solid-state imaging device 7 according to the seventh embodiment or the solid-state imaging device 8 according to the eighth embodiment to provide the second semiconductor layer 21 with the memory element 208 and the capacitor 206 or the resistor 207.

Further, the solid-state imaging device 9 according to the ninth embodiment may be combined with the solid-state imaging device 7 according to the seventh embodiment and the solid-state imaging device 8 according to the eighth embodiment to provide the second semiconductor layer 21 with the memory element 208, the capacitor 206, and the resistor 207.

### 10. Application Example to Mobile Body

The technology according to the present disclosure (the present technology) is applicable to various products. For example, the technology according to the present disclosure may be implemented as a device to be mounted on any kind of mobile body, for example, an automobile, an electric automobile, a hybrid electric automobile, a motorcycle, a bicycle, a personal mobility, an aircraft, a drone, a vessel, or a robot.

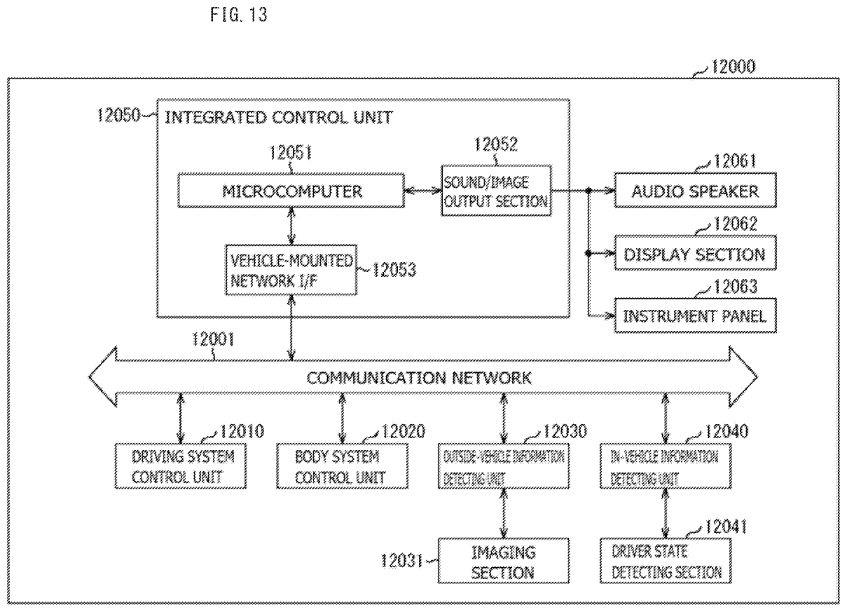

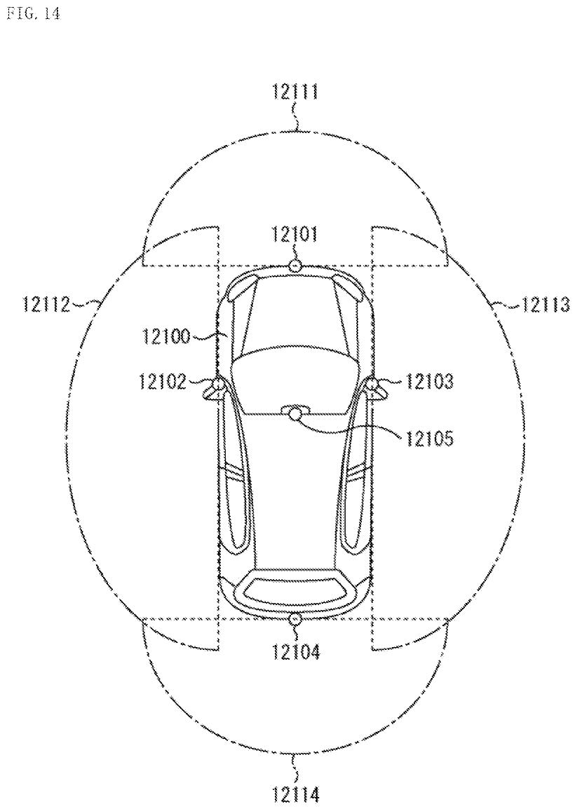

FIG. 13 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 13, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (UF) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 13, an audio speaker 12061, a display section 12062, and an instrument panel 12063 are illustrated as the output device. The display section 12062 may, for example, include at least one of an on-board display and a head-up display.

FIG. 14 is a diagram depicting an example of the installation position of the imaging section 12031.

In FIG. 14, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 14 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the forgoing, described is one example of the vehicle control system to which the technology according to the present disclosure is applicable. The technology according to the present disclosure is applicable to the imaging section 12031 out of the components described above. Applying the technology according to the present disclosure to the imaging section 12031 makes it possible to achieve the imaging section 12031 with a simpler configuration.

### 11. Application Example to Endoscopic Surgery System

A technology according to the present disclosure (the present technology) is applicable to various products. For example, the technology according to the present disclosure may be applied to an endoscopic surgery system.

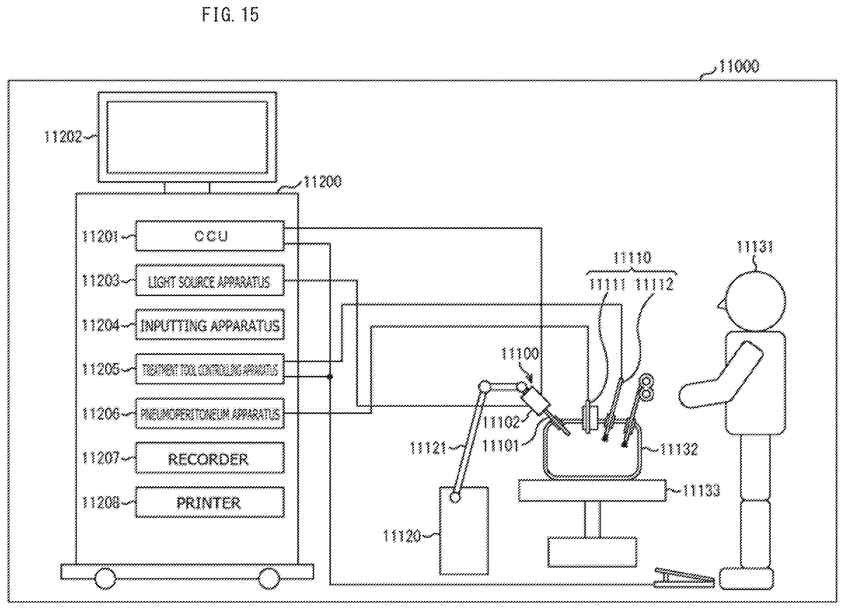

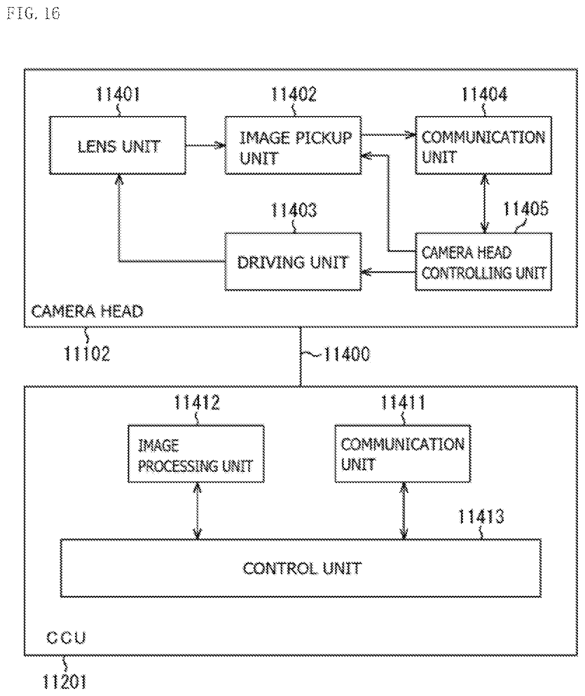

FIG. 15 is a view depicting an example of a schematic configuration of an endoscopic surgery system to which the technology according to an embodiment of the present disclosure (present technology) can be applied.

In FIG. 15, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

FIG. 16 is a block diagram depicting an example of a functional configuration of the camera head 11102 and the CCU 11201 depicted in FIG. 15.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

In the forgoing, described is one example of the endoscopic surgery system to which the technology according to the present disclosure may be applied. The technology according to the present disclosure may be applied to, for example, the imaging section 11402 of the camera head 11102 out of the components as described above. Applying the technology according to the present disclosure to the imaging section 11402 makes it possible to achieve simplification of a structure and obtain a favorable image of a surgery site.

It should be noted that although the endoscopic surgery system is described as an example here, the technology according to the present disclosure may be applied to, for example, a microscope surgery system or the like in addition thereto.

### 12. Other Embodiments

The present technology is not limited to the above-described embodiments and may be modified in a variety of manners without departing from the gist thereof.

For example, out of the solid-state imaging devices according to the first embodiment to the ninth embodiment described above, the solid-state imaging devices according to two or more of the embodiments may be combined.

In addition, the present technology is applied to the solid-state imaging device including the two layers, i.e., the first semiconductor layer and the second semiconductor layer, on the third base; however, it is also applicable to a case where three or more semiconductor layers are provided on the third base.

In the present disclosure, the solid-state imaging device includes a first semiconductor layer and a second semiconductor layer. A pixel is arranged in a matrix along a plane direction in the first semiconductor layer. The pixel includes a photoelectric converter. The number of the pixel is two or more. The second semiconductor layer is stacked on the first semiconductor layer on an opposite side to a light-incoming side of the pixel. The second semiconductor layer includes a first transistor electrically coupled to the pixel and having a gate lengthwise direction inclined with respect to an arrangement direction of the pixel.

The first transistor is thus provided in the second semiconductor layer independently of the arrangement of the pixel, which allows for miniaturization of the pixel in the first semiconductor layer. Additionally, it is possible to increase the gate length dimension of the first transistor by inclining the gate lengthwise direction of the first transistor with respect to the arrangement direction of the pixel, which makes it possible to improve the electrical properties of the first transistor.

### <Configuration of Present Technology>

The present technology includes the following configuration.

(1)

A solid-state imaging device including:
a first semiconductor layer in which a pixel is arranged in a matrix along a plane direction, the pixel including a photoelectric converter, number of the pixel being two or more; and
a second semiconductor layer stacked on the first semiconductor layer on an opposite side to a light-incoming side of the pixel and including a first transistor, the first transistor being electrically coupled to the pixel and having a gate lengthwise direction inclined with respect to an arrangement direction of the pixel.

(2)

The solid-state imaging device according to (1) described above, in which
the pixel has a rectangular shape in a plan view, and
the gate lengthwise direction of the first transistor is parallel with a diagonal direction of the pixel in the plan view.

(3)

The solid-state imaging device according to (1) or (2) described above, in which the first transistor constitutes a pixel circuit coupled to the pixel.

(4)

The solid-state imaging device according to (3) described above, in which the first transistor includes an amplifier transistor, a selection transistor, a reset transistor, or a floating diffusion conversion gain switching transistor that constitutes the pixel circuit.

(5)

The solid-state imaging device according to (4) described above, in which a gate length of the amplifier transistor is longer than a gate length of the selection transistor or the reset transistor.

(6)

The solid-state imaging device according to (4) or (5) described above, in which a plurality of the amplifier transistors is electrically coupled in parallel with respect to one the pixel circuit.

(7)

The solid-state imaging device according to any one of (1) to (6) described above, further including:
a first terminal provided on a side of the first semiconductor layer toward the second semiconductor layer, the first terminal being electrically coupled to the pixel via a first wiring layer; and
a second terminal provided on a side of the second semiconductor layer toward the first semiconductor layer, the second terminal being electrically coupled to the first transistor via a second wiring layer and bonded to the first terminal.

(8)

The solid-state imaging device according to any one of (1) to (6) described above, further including a penetrating wiring line penetrating the second semiconductor layer from the first semiconductor layer to electrically couple the pixel and the first transistor to each other.

(9)

The solid-state imaging device according to any one of (3) to (8) described above, further including a third semiconductor layer that is stacked on an opposite side of the second semiconductor layer to the first semiconductor layer and on which a peripheral circuit is mounted, the peripheral circuit including a second transistor and controlling the pixel circuit.

(10)

The solid-state imaging device according to (9) described above, in which a gate lengthwise direction of the second transistor is parallel with the arrangement direction of the pixel.

(11)

The solid-state imaging device according to any one of (1) to (10) described above, in which one or more elements selected from among a metal body/dielectric body/semiconductor capacitor, a resistor, and a memory element are further provided in the second semiconductor layer.

(12)

The solid-state imaging device according to (11) described above, in which
the metal body/dielectric body/semiconductor capacitor includes a metal body as a first electrode and a semiconductor as a second electrode, the metal body having a rectangular shape in a plan view, and
a centerline of the first electrode is parallel with the gate lengthwise direction of the first transistor.

(13)

The solid-state imaging device according to (11) or (12) described above, in which a resistor lengthwise direction of the resistor is parallel with the gate lengthwise direction of the first transistor.

(14)

The solid-state imaging device according to any one of (11) to (13) described above, in which
the memory element includes paired main electrodes, a channel formation region provided between the main electrodes, a ferroelectric body provided on the channel formation region, and a gate electrode provided on the ferroelectric body, and
a gate lengthwise direction of the memory element is parallel with the gate lengthwise direction of the first transistor.

This application claims the priority on the basis of Japanese Patent Application No. 2021-041892 filed on Mar. 15, 2021 with Japan Patent Office, the entire contents of which are incorporated in this application by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A solid-state imaging device comprising:
a first semiconductor layer in which a pixel is arranged in a matrix along a plane direction, the pixel including a photoelectric converter, number of the pixel being two or more; and
a second semiconductor layer stacked on the first semiconductor layer on an opposite side to a light-incoming side of the pixel and including a first transistor, the first transistor being electrically coupled to the pixel and having a gate lengthwise direction inclined with respect to an arrangement direction of the pixel.

2. The solid-state imaging device according to claim 1, wherein
the pixel has a rectangular shape in a plan view, and
the gate lengthwise direction of the first transistor is parallel with a diagonal direction of the pixel in the plan view.

3. The solid-state imaging device according to claim 1, wherein the first transistor constitutes a pixel circuit coupled to the pixel.

4. The solid-state imaging device according to claim 3, wherein the first transistor comprises an amplifier transistor, a selection transistor, a reset transistor, or a floating diffusion conversion gain switching transistor that constitutes the pixel circuit.

5. The solid-state imaging device according to claim 4, wherein a gate length of the amplifier transistor is longer than a gate length of the selection transistor or the reset transistor.

6. The solid-state imaging device according to claim 4, wherein a plurality of the amplifier transistors is electrically coupled in parallel with respect to one the pixel circuit.

7. The solid-state imaging device according to claim 1, further comprising:
a first terminal provided on a side of the first semiconductor layer toward the second semiconductor layer, the first terminal being electrically coupled to the pixel via a first wiring layer; and
a second terminal provided on a side of the second semiconductor layer toward the first semiconductor layer, the second terminal being electrically coupled to the first transistor via a second wiring layer and bonded to the first terminal.

8. The solid-state imaging device according to claim 1, further comprising a penetrating wiring line penetrating the second semiconductor layer from the first semiconductor layer to electrically couple the pixel and the first transistor to each other.

9. The solid-state imaging device according to claim 3, further comprising a third semiconductor layer that is stacked on an opposite side of the second semiconductor layer to the first semiconductor layer and on which a peripheral circuit is mounted, the peripheral circuit including a second transistor and controlling the pixel circuit.

10. The solid-state imaging device according to claim 9, wherein a gate lengthwise direction of the second transistor is parallel with the arrangement direction of the pixel.

11. The solid-state imaging device according to claim 1, wherein one or more elements selected from among a metal body/dielectric body/semiconductor capacitor, a resistor, and a memory element are further provided in the second semiconductor layer.

12. The solid-state imaging device according to claim 11, wherein
the metal body/dielectric body/semiconductor capacitor includes a metal body as a first electrode and a semiconductor as a second electrode, the metal body having a rectangular shape in a plan view, and
a centerline of the first electrode is parallel with the gate lengthwise direction of the first transistor.

13. The solid-state imaging device according to claim 11, wherein a resistor lengthwise direction of the resistor is parallel with the gate lengthwise direction of the first transistor.

14. The solid-state imaging device according to claim 11, wherein
the memory element includes paired main electrodes, a channel formation region provided between the main electrodes, a ferroelectric body provided on the channel formation region, and a gate electrode provided on the ferroelectric body, and
a gate lengthwise direction of the memory element is parallel with the gate lengthwise direction of the first transistor.
